(19) United States
(12) Patent Application Publication
(10) Pub. No.: US 2023/0113864 A1
(43) Pub. Date: Apr. 13, 2023

(54) METHOD AND ARRANGEMENT FOR SIMULATING THE MOTION OF A ROTATABLE BODY

(71) Applicant: dSPACE GmbH, Paderborn (DE)

(72) Inventors: Kusnadi LIEM, Paderborn (DE); Norbert MEYER, Paderborn (DE); Frank SCHULTE, Paderborn (DE)

(73) Assignee: dSPACE GmbH, Paderborn (DE)

(21) Appl. No.: 17/954,063

(22) Filed: Sep. 27, 2022

(30) Foreign Application Priority Data
Sep. 28, 2021 (DE) 10 2021 125 156.7

(51) Int. Cl. G06F 30/15; B60W 10/184; G06F 30/20

(52) U.S. Cl. CPC G06F 30/15; B60W 10/184; G06F 30/20; B60W 2520/30; B60W 2520/40

(57) ABSTRACT

A method and an arrangement for simulating the motion of a rotatable body in a simulation computer using a brake test bench, which has an engine, a real rotatable body representing the simulated rotatable body and a brake. The method includes the method steps of: specifying a target speed, applying this target speed to the engine, rotating the real rotatable body, specifying a braking value, controlling the brake on the basis of the specified braking value, measuring the actual torque and the actual speed of the real rotatable body, determining whether the actual speed exceeds a predetermined limit speed, and simulating the motion of the rotatable body on the basis of a torque of the simulated rotatable body. In this way, a possibility for simulating the motion of a rotatable body is provided, which provides at least approximately correct results even for low speeds of the rotatable body.

This nonprovisional application claims priority under 35 U.S.C. § 119(a) to German Patent Application No. 10 2021 125 156.7, which was filed in Germany on Sep. 28, 2021, and which is herein incorporated by reference.

### BACKGROUND OF THE INVENTION

### Field of the Invention

The present invention relates to a method for simulating the motion of a rotatable body in a simulation computer using a brake test bench, having an engine, a real rotatable body representing the simulated rotatable body and a brake for braking the real rotatable body, comprising the following method steps: specifying a target speed using the simulation computer; applying this target speed to the engine; rotating the real rotatable body by means of the engine pressurized with the target speed; specifying a braking value using the simulation computer; controlling the brake acting on the real rotatable body on the basis of the specified braking value; measuring the actual torque and the actual speed of the real rotatable body; and/or simulating the motion of the rotatable body in the simulation computer based on a torque of the simulated rotatable body corresponding to the measured actual torque of the real rotatable body.

The invention further relates to an arrangement for simulating the motion of a rotatable body using a brake test bench and a simulation computer, wherein the brake test bench includes a real rotatable body; an engine for rotating the real rotatable body; a brake which, to slow down the rotation of the real rotatable body, can act on the real rotatable body; a torque sensor for measuring the actual torque of the real rotatable body and a speed sensor for measuring the actual speed of the real rotatable body; and wherein the simulation computer is set up to specify a target speed for applying this target speed to the engine and a braking value for controlling the brake, as well as to simulate the motion of the rotatable body in the simulation computer on the basis of a torque of the simulated rotatable body, which corresponds to an actual torque of the real rotatable body measured with the torque sensor.

### Description of the Background Art

Braking systems for engine vehicles, like all dry friction-based systems, are difficult to model. Therefore, it generally makes sense to integrate the brake as a real load in a real-time test. For this purpose, a rotatable body, typically a wheel, is controlled by an engine to a speed specified by the model and at the same time braked by one of the brakes. Its applied brake force is read out and used in the model. At low revs, however, the engine does not manage to maintain the rotation specified by the model. This can lead to an undesirable stopping of the wheel, which distorts the simulation result.

Specifically, with conventional brake test benches, the pressure and torque are measured on the real brake. These signals are transferred to a computer vehicle dynamics model and processed there. The model runs on real-time hardware. Incidentally, the rest of the entire vehicle and its surroundings are simulated in a simulation environment. The model delivers either the target wheel speed or the target vehicle speed and the target pressure of the brake cylinders to the brake test bench, which are adjusted on the brake test bench. This results in a closed control loop.

Control units for vehicle dynamics control functions such as ABS and ESP can be tested. In addition, real driving profiles and defined test cycles can be run in the simulation environment, while the brake test bench provides information about the real load and wear of the brake. As part of the electrification of the powertrain, the influence of recuperation on the brake and thus also on the braking behavior can be tested.

If the real wheel comes to a standstill on the brake test bench, even though the virtual vehicle is still moving forward, conventional configurations of the brake test bench show faulty behavior. The torque sensor measures a torque of zero value on the stationary wheel and provides a corresponding signal. The simulation environment calculates a braking torque therefrom with a value of zero. The simulated brake of the virtual vehicle becomes ineffective to a certain extent. Although the model specifies a brake pressure of the simulated brake and the test bench also implements the specified brake pressure on the real brake, no brake force acts on the virtual vehicle. It is obvious that under such unrealistic test conditions, no meaningful test of a control system for driving dynamics is possible. Studies of stress and wear are also falsified.

The undesired stopping of the wheel is due to a well-known mechanical problem known as stick-slip dynamics. Dry friction contact surfaces tend to tilt into each other and stop at low relative speed. In a coasting vehicle, this effect does not occur because of the large flywheel mass of the vehicle, but in the brake test bench, the rotation is imparted by an engine that is too weak to simulate this flywheel mass at low rotational speed, unless it is enormously oversized. On the other hand, it is desirable to integrate a brake as a real load into the test bench, because dry friction can hardly be realistically modeled. There is no universal mathematical description for dry friction between two contact surfaces; it depends on too many individual factors.

### SUMMARY OF THE INVENTION

It is therefore an object of the present invention to provide a possibility for simulating the motion of a rotatable body, which simulation provides at least approximately correct results even for low speeds of the rotatable body.

According to an exemplary embodiment of the invention, a method for simulating the motion of a rotatable body in a simulation computer using a brake test bench is thus provided, which comprises an engine, a real rotatable body representing the simulated rotatable body, and a brake for braking the real rotatable body, comprising the following method steps: specifying a target speed using the simulation computer; applying this target speed to the engine; rotating the real rotatable body by means of the engine pressurized with the target speed; specifying a braking value using the simulation computer; controlling the brake acting on the real rotatable body on the basis of the specified braking value; measuring the actual torque and the actual speed of the real rotatable body; determining whether the actual speed exceeds a predetermined limit speed; and simulating the motion of the rotatable body in the simulation computer based on a torque of the simulated rotatable body corresponding to the measured actual torque of the real rotatable body, if the actual speed exceeds the predetermined limit speed, or simulating the motion of the rotatable body in the simulation computer on the basis of a calculated value for the torque of the simulated rotatable body, if the actual speed does not exceed the predetermined limit value.

When the present case refers to “actual torque of the real rotatable body” and “torque of the simulated rotatable body”, this refers to a torque acting on the rotatable body by the brake in the real world or in the simulation. A determined torque value is an estimated torque value based on values measured in the immediate past, using different methods for performing the estimation, some of which are disclosed in the description below.

It is thus an essential aspect of the invention that at low speeds, instead of the measured brake force, a determined value is used, which is determined from a measurement or from several measurements that have previously been carried out at a sufficiently high speed.

Preferably, the value for the torque of the simulated rotatable body is determined on the basis of actual torques previously measured as a function of the actual speed. In this context, it is particularly preferred that the value for the torque of the simulated rotatable body is determined by extrapolation of previously measured actual torques as a function of the actual speed. It is preferably provided in particular that the actual torques previously measured for extrapolation as a function of the actual speed have only been measured after the actual speed has approximated the limit speed by a predetermined measure. In this way, it can be ensured that in order to determine the torque value of the simulated rotatable body, such measured actual torques are used, which belong to actual speeds that are not too far from the limit speed, so that the most realistic values for the torque of the simulated rotatable body are obtained.

In principle, it is possible to carry out this extrapolation as a purely geometric extrapolation without model assumptions, in particular without assuming a special friction characteristic. Preferably, however, the extrapolation is carried out on the basis of a parameterizable friction model, the parameters of which are adapted to the actual torques previously measured as a function of the actual speed. This also leads to the most realistic values for the torque of the simulated rotatable body being obtained.

In principle, it is sufficient for the invention to take into account the measured actual torque. Preferably, however, the method has the following additional method step: measuring the actual brake pressure of the brake acting on the real rotatable body, and

Determining the torque value of the simulated rotatable body, taking into account the measured actual torque and the measured actual brake pressure. In this context, the determination of the value for the torque of the simulated rotatable body is preferably carried out taking into account the measured actual torque and the measured actual brake pressure using a Kalman filter.

As is well known, a Kalman filter is a mathematical method for iterative estimation of parameters for describing system states based on error-prone observations. The Kalman filter is used to determine system variables that are not directly measurable, at least approximately, while the errors of the measurements are reduced as well as possible. For dynamic quantities, a mathematical model can be added to the filter as a constraint to account for dynamic relationships between the system variables. For example, equations of motion can help to jointly determine changing positions and speeds quite precisely. In particular, the Kalman filter in the present case allows for a more precise determination of the value for the torque of the simulated rotatable body, if both the measured actual torque and the measured actual brake pressure are taken into account to determine the value for the torque of the simulated rotatable body.

Preferably, it is also true that the simulated rotatable body and the real rotatable body is a simulated or real engine vehicle wheel arrangement with wheel, brake disc and wheel axle. Furthermore, it is preferably provided that the braking value, and thus also the actual braking value, is a brake pressure, a brake force, or a braking torque.

In principle, it may be provided that the predetermined limit speed is zero. Preferably, however, the predetermined limit speed is a value greater than zero. This means that even before the rotatable body blocks for the first time, the determined value for the torque of the simulated rotatable body is used and the measured value is ignored.

Different methods are conceivable for determining the value for the torque of the simulated rotatable body. In this respect, it is advantageous to always keep a series of consecutive measured values in a ring buffer in order to then, if the actual speed does not exceed the predetermined limit speed and in this respect a determined value for the torque of the simulated rotatable body is required, to have an extrapolated series of measurements instead of just a single measured value. The extrapolation can be carried out on the basis of a parameterizable friction model, the parameters of which are adapted to the measurement series, or on the basis of a mathematical extrapolation method without assuming a special friction characteristic.

The invention further relates to an arrangement for simulating the motion of a rotatable body using a brake test bench and a simulation computer, wherein the brake test bench is a real rotatable body; an engine for rotating the real rotatable body; a brake which, to slow down the rotation of the real rotatable body, acts on the real rotatable body; a torque sensor for measuring the actual torque of the real rotatable body; and a speed sensor for measuring the actual speed of the real rotatable body; and wherein the simulation computer is set up to specify a target speed for applying this target speed to the engine and a braking value for controlling the brake, as well as to simulate the motion of the rotatable body in the simulation computer on the basis of a torque of the simulated rotatable body, which corresponds to an actual torque of the real rotatable body measured with the torque sensor if the actual speed measured with the tachometer exceeds a predetermined limit speed, or to simulate the motion of the rotatable body in the simulation computer on the basis of a determined value for the torque of the simulated rotatable body if the actual speed measured with the tachometer does not exceed the predetermined limit speed.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows schematically, an arrangement for simulating the motion of a rotatable body according to an embodiment of the invention; and

FIG. 2 shows schematically, the sequence of a method for operating the arrangement from FIG. 1.

### DETAILED DESCRIPTION

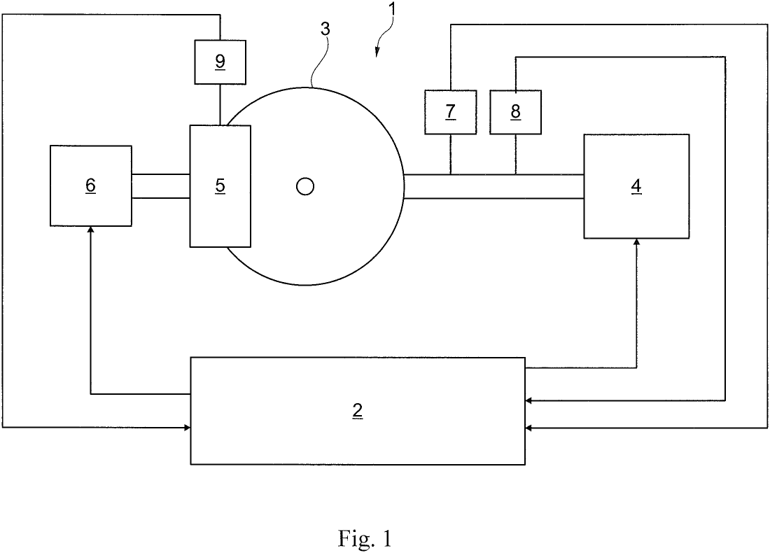

FIG. 1 schematically shows an arrangement for simulating the motion of a rotatable body 3 with a brake test bench 1 and a simulation computer 2 according to an embodiment of the invention. In the present case, the rotatable body 3 is a wheel that represents a wheel of an engine vehicle to be simulated but does not have to be designed exactly like the wheel to be simulated. In the present case, the aim is to test the dynamics of this wheel during braking by simulation.

For this purpose, the brake test bench 1 has, in addition to the real rotatable body 3, an engine 4 for rotating the real rotatable body 3 and a brake 5, which, to slow down the rotation of the real rotatable body 3, can act on the real rotatable body 3. To rotate the real rotatable body 3, it is coupled to the engine 4 via a drive shaft 10. The brake 5 is controlled by means of a brake force generator 6. In addition, the brake test bench 1 is equipped with a torque sensor 7 for measuring the actual torque of the real rotatable body 3 and a speed sensor 8 for measuring the actual speed of the real rotatable body 3.

The simulation computer 2 is set up to specify a target speed for applying this target speed to the engine 4 and, as indicated by a corresponding arrow, to supply it to the engine 4. In addition, the simulation computer 2 is set up to specify a brake force for controlling the brake 5 as the braking value and, as also indicated with a corresponding arrow, supply it to the brake force generator 6.

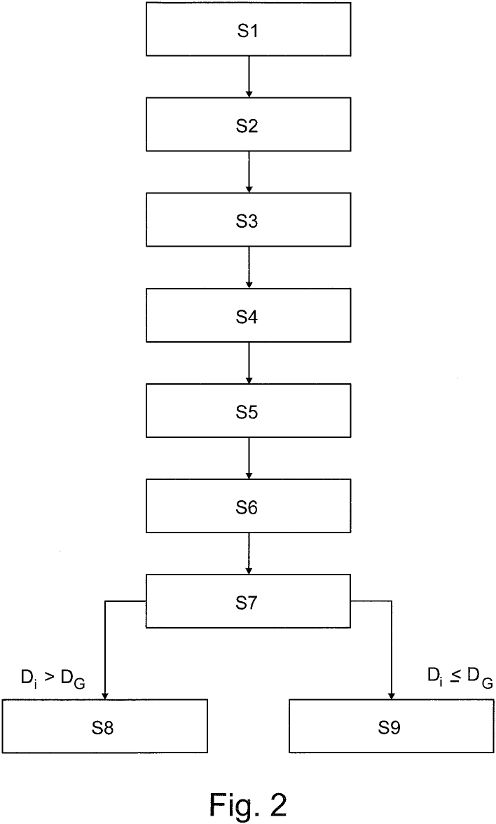

Specifically, the method for simulating the motion of the rotatable body 3 in the simulation computer 2 using the brake test bench described above is as follows. This is shown schematically in FIG. 2:

In a first step S1, a target speed is specified using the simulation computer 2. With this target speed, the engine 4 is pressurized in step S2. In step S3, a rotation of the real rotatable body 3 takes place. Furthermore, in step S4, a braking value is specified by means of the simulation computer 2, so that in step S5, a control of the brake 5 acting on the real rotatable body 3 is carried out on the basis of the specified braking value. For this purpose, the brake force generator 6 acting on the brake 5 is controlled accordingly by the simulation computer 2.

In step S6, the actual torque and the actual speed of the real rotatable body 3 are measured as well as the actual brake pressure of the brake acting on the real rotatable body 3. The actual torque and the actual speed of the real rotatable body 3 are supplied to the simulation computer 2, as indicated by corresponding arrows in FIG. 1. In step S7, the simulation computer 2 determines whether the actual speed exceeds a predetermined limit speed. In the present case, that limit speed is fixed in such a way that, although it has only a low value, it is different from zero.

In step S8, the motion of the rotatable body 3 in the simulation computer 2 is then simulated on the basis of a torque of the simulated rotatable body, which corresponds to the measured actual torque of the real rotatable body 3, if the actual speed, designated in FIG. 2 with Dᵢ, exceeds the predetermined limit speed, designated in FIG. 2 with D_{G}. Alternatively, in step S9, the motion of the rotatable body is simulated in the simulation computer on the basis of a determined value for the torque of the simulated rotatable body, if the actual speed does not exceed the predetermined limit speed.

Specifically, the value for the torque of the simulated rotatable body is determined by extrapolating actual torques previously measured as a function of the actual speed. However, the actual torques previously measured for extrapolation as a function of the actual speed have only been measured after the actual speed has approached the limit speed by a predetermined measure. In this way, it can be ensured that, in order to determine the torque value of the simulated rotatable body, such measured actual torques are used, which belong to actual speeds that are not too far from the limit speed, so that mostly realistic values for the torque of the simulated rotatable body are obtained. The extrapolation is carried out here on the basis of a parameterizable friction model, the parameters of which are adapted to the actual torques previously measured as a function of the actual speed.

As explained above, the actual brake pressure of the brake 5 acting on the real rotatable body 3 was also measured in step S6. Although it would not be necessary in principle to take this value into account, in the present case the value for the torque of the simulated rotatable body is determined taking into account the measured actual torque and the measured actual brake pressure. This determination is done using a Kalman filter, which further improves the approximation to a realistic value.

Overall, at low speeds, instead of the measured brake force, a determined value is used, which is determined from a measurement or from several measurements that have previously been carried out at a sufficiently high speed. In this way, the problem of the rotatable body 3 stopping and incorrect values being delivered, which would lead to incorrect simulation results, is avoided.

In summary, the effect of the method described here is as follows: The rotatable body 3 of the brake test bench 1 rotates at a nominal speed. A braking torque applied by a real brake 5 acts on the rotatable body 3. As soon as a blockage of the rotatable body 3 turns the rotational speed to zero, although the target speed specifies a value other than zero, the measured torque of the brake 5 is also zero, and consequently, also the braking effect derived from the measured torque in the model. However, the torque determined by the approach described above provides a realistic torque even when the rotatable body 3 is blocked.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for simulating a motion of a rotatable body in a simulation computer using a brake test bench that comprises an engine, a real rotatable body representing the simulated rotatable body and a brake for braking the real rotatable body, the method comprising:
specifying a target speed using the simulation computer;
applying this target speed to the engine;
rotating the real rotatable body via the engine pressurized with the target speed;
specifying a braking value using the simulation computer;
controlling the brake acting on the real rotatable body on the basis of the specified braking value;
measuring the actual torque and the actual speed of the real rotatable body;
determining whether the actual speed exceeds a predetermined limit speed, and
simulating the motion of the rotatable body in the simulation computer on the basis of a torque of the simulated rotatable body corresponding to the measured actual torque of the real rotatable body if the actual speed exceeds the predetermined limit speed, or simulating the motion of the rotatable body in the simulation computer on the basis of a determined value for the torque of the simulated rotatable body if the actual speed does not exceed the predetermined limit speed.

2. The method according to claim 1, wherein the value for the torque of the simulated rotatable body is determined on the basis of actual torques previously measured as a function of the actual speed.

3. The method according to claim 2, wherein the value for the torque of the simulated rotatable body is determined by extrapolation of previously measured actual torques as a function of the actual speed.

4. The method according to claim 3, wherein the actual torques previously measured for the extrapolation as a function of the actual speed have only been measured after the actual speed has approximated the limit speed by a predetermined measure.

5. The method according to claim 3, wherein the extrapolation is carried out on the basis of a parameterizable friction model, the parameters of which are adapted to the actual torques previously measured as a function of the actual speed.

6. The method according to claim 1, further comprising:
measuring the actual brake pressure of the brake acting on the real rotatable body; and
determining the torque value of the simulated rotatable body, taking into account the measured actual torque and the measured actual brake pressure.

7. The method according to claim 6, wherein the determination of the value for the torque of the simulated rotatable body is carried out taking into account the measured actual torque and the measured actual brake pressure using a Kalman filter.

8. An arrangement for simulating a motion of a rotatable body the arrangement comprising:
a brake test bench comprising a real rotatable body, an engine for rotating the real rotatable body, a brake which, to slow down the rotation of the real rotatable body, acts on the real rotatable body, a torque sensor for measuring the actual torque of the real rotatable body, and a speed sensor for measuring the actual speed of the real rotatable body;
a simulation computer configured to specify a target speed for applying this target speed to the engine and a braking value for controlling the brake and to simulate the motion of the rotatable body in the simulation computer on the basis of a torque of the simulated rotatable body corresponding to an actual torque of the real rotatable body measured with the torque sensor if the actual speed measured with the tachometer exceeds a predetermined limit speed, or to simulate the motion of the rotatable body in the simulation computer on the basis of a determined value for the torque of the simulated rotatable body if the actual speed measured with the tachometer does not exceed the predetermined limit speed.

9. The arrangement according to claim 8, wherein the brake test bench further comprises a pressure sensor for measuring the actual brake pressure of the brake, which acts on the real rotatable body, and wherein the simulation computer is set up to determine the torque value of the simulated rotatable body, taking into account the measured actual torque and the measured actual brake pressure.

10. The arrangement according to claim 9, wherein the simulation computer is equipped with a Kalman filter for determining the value for the torque of the simulated rotatable body, taking into account the measured actual torque and the measured actual brake pressure.
